(19) United States
(12) Patent Application Publication
(10) Pub. No.: US 2019/0088318 A1
(43) Pub. Date: Mar. 21, 2019

(54) MEMORY DEVICE

(71) Applicant: TOSHIBA MEMORY CORPORATION, Tokyo (JP)

(72) Inventor: Tetsu MOROOKA, Yokkaichi Mie (JP)

(73) Assignee: TOSHIBA MEMORY CORPORATION, Tokyo (JP)

(21) Appl. No.: 15/909,535

(22) Filed: Mar. 1, 2018

(30) Foreign Application Priority Data
Sep. 15, 2017 (JP) 2017-178417

(51) Int. Cl. G11C 13/00; G11C 11/56

(52) U.S. Cl. CPC G11C 13/0004; G11C 11/5614; G11C 13/004; G11C 13/0007

(57) ABSTRACT

A memory device includes: a first conductive layer extending in a first direction, and a second conductive layer extending in a second direction intersecting with the first direction. A third conductive layer is electrically connected to the second conductive layer. A variable resistance layer includes a first layer containing a semiconductor or a first metal oxide and a second layer located between the first layer and the second conductive layer and containing a second metal oxide. The second layer includes a first end and a second end spaced from the third conductive layer farther than the first end. An intermediate layer is provided between the variable resistance layer and the second conductive layer and has a resistivity higher than that of the second layer. An insulator is provided between the first end and the second conductive layer and has a resistivity higher than that of the second layer.

### CROSS-REFERENCE TO RELATED APPLICATION

This application claims the benefit of and priority to Japanese Patent Application No. 2017-178417, filed Sep. 15, 2017, the entire contents of which are incorporated herein by reference.

### FIELD

Embodiments described herein relate generally to a memory device.

### BACKGROUND

In a resistance-change type memory, a current flows by applying a voltage to a variable resistance layer of a memory cell to make a transition between a high resistance state and a low resistance state. For example, when the high resistance state is defined as data “0” and the low resistance state is defined as data “1”, the memory cell can store 1-bit data of “0” and “1”. In order to increase the degree of integration of the resistance-change type memory, the resistance-change type memory may be formed to have a three-dimensional structure in which memory cells MCs are three-dimensionally arranged. Malfunction of the memory cell MC may often occur due to a process of forming the three-dimensional structure.

### DESCRIPTION OF THE DRAWINGS

FIG. 1 is a block diagram of a memory device according to a first embodiment;

FIG. 2 is an equivalent circuit diagram of a memory cell array according to the first embodiment;

FIG. 3 is a schematic cross-sectional view of the memory cell array of the memory device according to the first embodiment;

FIG. 4 is a schematic cross-sectional view illustrating the memory device which is being manufactured by a method of manufacturing the memory device according to the first embodiment;

FIG. 5 is a schematic cross-sectional view illustrating the memory device which is being manufactured by a method of manufacturing the memory device according to the first embodiment;

FIG. 6 is a schematic cross-sectional view illustrating the memory device which is being manufactured by a method of manufacturing the memory device according to the first embodiment;

FIG. 7 is a schematic cross-sectional view illustrating the memory device which is being manufactured by a method of manufacturing the memory device according to the first embodiment;

FIG. 8 is a schematic cross-sectional view illustrating the memory device which is being manufactured by a method of manufacturing the memory device according to the first embodiment;

FIG. 9 is a schematic cross-sectional view illustrating the memory device which is being manufactured by a method of manufacturing the memory device according to the first embodiment;

FIG. 10 is a schematic cross-sectional view illustrating the memory device which is being manufactured by a method of manufacturing the memory device according to the first embodiment;

FIG. 11 is a schematic cross-sectional view illustrating a memory device which is being manufactured by a method of manufacturing a memory device according to a comparative embodiment;

FIG. 12 is a schematic cross-sectional view of a memory cell array of the memory device according to a comparative example;

FIG. 13 is a view for describing problems of the memory device according to the comparative example;

FIG. 14 is a schematic cross-sectional view of a memory cell array of a memory device according to a second embodiment; and

FIG. 15 is a schematic cross-sectional view of a memory cell array of a memory device according to a third embodiment.

### DETAILED DESCRIPTION

An exemplary embodiment provides a memory device capable of preventing malfunction of a memory cell MC.

In general, according to one embodiment, a memory device includes: a first conductive layer that extends in a first direction; a second conductive layer that extends in a second direction intersecting with the first direction; a third conductive layer that is electrically connected to the second conductive layer; a variable resistance layer that includes a first layer containing a semiconductor or a first metal oxide and a second layer located between the first layer and the second conductive layer and containing a second metal oxide, the second layer including a first end and a second end spaced from the third conductive layer farther than the first end, and provided between the first conductive layer and the second conductive layer; an intermediate layer that is provided between the variable resistance layer and the second conductive layer and having resistivity higher than that of the second layer; and an insulator that is provided between the first end and the second conductive layer and has resistivity higher than that of the second layer.

Hereafter, embodiments of the disclosure will be described with reference to the accompanying drawings. In the following description, the same or similar components will be represented by like reference numerals, and the descriptions of components which have been described once will be properly omitted.

In the specification, the terms such as ‘upper’ and ‘lower’ are used for convenience of description. The terms such as ‘upper’ and ‘lower’ only indicate a relative positional relation in the drawings, and do not define a positional relation in the direction of gravity.

The qualitative analysis and quantitative analysis for chemical compositions of members constituting a memory device in the specification can be performed through SIMS (Secondary Ion Mass Spectroscopy) and EDX (Energy Dispersive X-ray Spectroscopy), for example. Moreover, the thicknesses of members constituting a semiconductor device and a distance between members can be measured through a TEM (Transmission Electron Microscope). Furthermore, whether a member constituting the memory device is amorphous can be determined by checking whether grains are present in the member, through observation with the TEM. In addition, the magnitude relation in resistivity between two members constituting the memory device can be determined by evaluation of the composition and crystallinity in the two members.

Embodiments of memory devices will be described below with reference to the drawings.

### First Embodiment

A memory device according to a first embodiment includes: a first conductive layer that extends in a first direction; a second conductive layer that extends in a second direction intersecting with the first direction; a third conductive layer that is electrically connected to the second conductive layer; a variable resistance layer that includes a first layer containing a semiconductor or a first metal oxide and a second layer located between the first layer and the second conductive layer and containing a second metal oxide, the second layer including a first end and a second end spaced from the third conductive layer farther than the first end, and provided between the first conductive layer and the second conductive layer; an intermediate layer that is provided between the variable resistance layer and the second conductive layer and having resistivity higher than that of the second layer; and an insulator that is provided between the first end and the second conductive layer and has resistivity higher than that of the second layer.

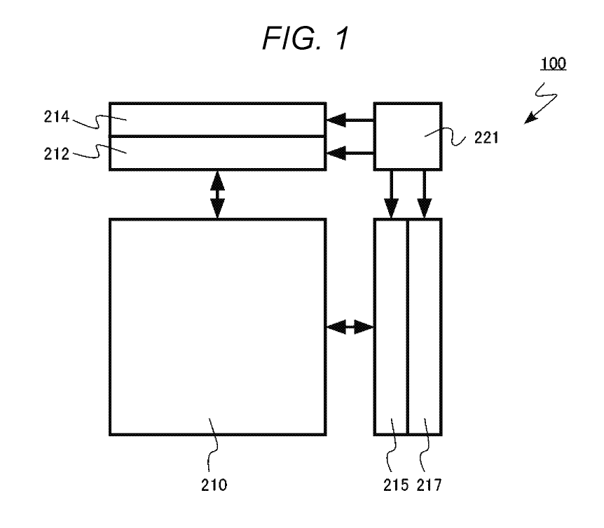

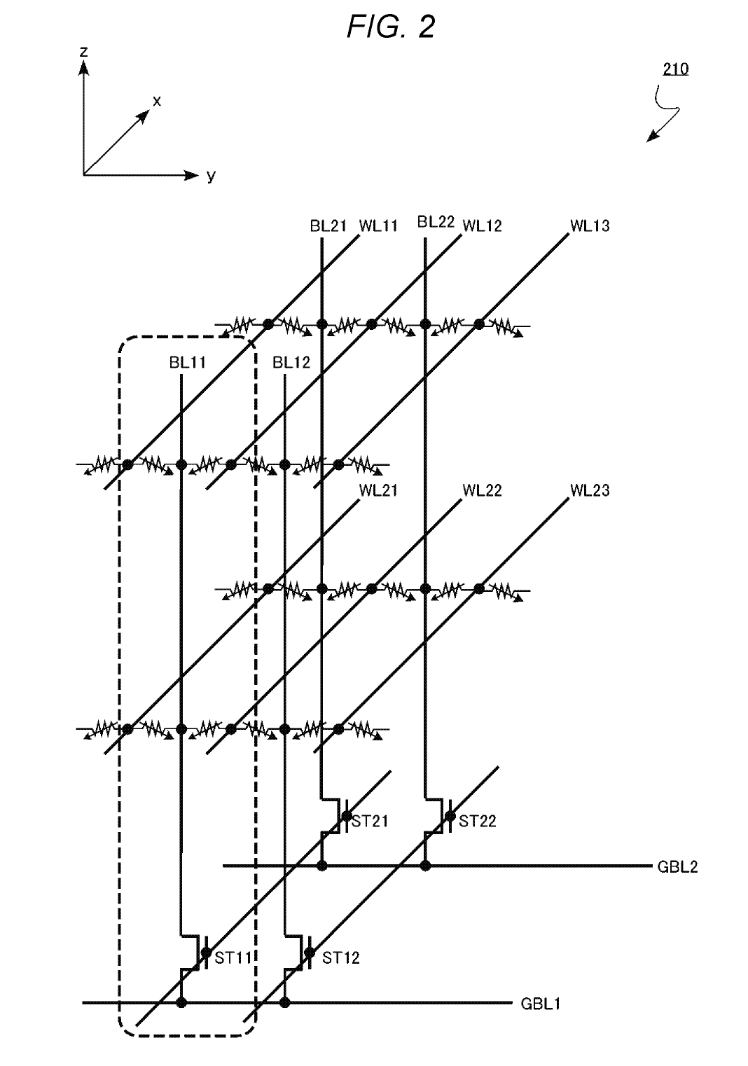

FIG. 1 is a block diagram of the memory device according to the first embodiment. FIG. 2 is an equivalent circuit diagram of a memory cell array of the memory device according to the first embodiment. The memory cell array of the first embodiment has a three-dimensional structure in which memory cells MCs are three-dimensionally arranged. The memory device of the first embodiment is a resistance-change type memory 100. The memory cell MC is a two-terminal resistance-variable element.

As illustrated in FIG. 1, the resistance-change type memory 100 includes a memory cell array 210, a word line driver circuit 212, a row decoder circuit 214, a sense amplifier 215, a column decoder circuit 217, and a control circuit 221.

As illustrated in FIG. 2, a plurality of memory cells MCs is three-dimensionally arranged in the memory cell array 210. The memory cell array 210 includes, for example, a plurality of word lines WLs (WL11, WL12, WL13, WL21, WL22, and WL23) and a plurality of bit lines BLs (BL11, BL12, BL21, and BL22). The word line WLs extend in an x-direction (first direction). The bit lines BLs extend in a z-direction (second direction). The word lines WLs and the bit lines BLs vertically intersect with each other. The memory cells MCs are arranged at intersections of the word lines WLs and the bit lines BLs.

The plurality of word lines WLs is electrically connected to the row decoder circuit 214. The plurality of bit lines BLs is connected to the sense amplifier 215. Between the plurality of bit lines BLs and the sense amplifier 215, select transistors STs (ST11, ST21, ST12, and ST22) and global bit lines GBLs (GBL1 and GBL2) are provided. A desired bit line BL is selected by the select transistor ST, and data of the selected bit line BL is transmitted to the sense amplifier 215 via the global bit line GBL.

The row decoder circuit 214 has a function of selecting the word line WL according to the input row address signal. The word line driver circuit 212 has a function of applying a predetermined voltage to the word line WL selected by the row decoder circuit 214.

The column decoder circuit 217 has a function of selecting the bit line BL according to the input column address signal. The sense amplifier 215 has a function of applying a predetermined voltage to the bit line BL selected by the column decoder circuit 217. Further, the sense amplifier 215 has a function of detecting and amplifying a current flowing between the selected word line WL and the selected bit line BL.

The control circuit 221 has a function of controlling the word line driver circuit 212, the row decoder circuit 214, the sense amplifier 215, the column decoder circuit 217, and other circuits (not illustrated).

The circuits, for example, the word line driver circuit 212, the row decoder circuit 214, the sense amplifier 215, the column decoder circuit 217, and the control circuit 221 are constituted by, for example, a transistor and an interconnection layer using a semiconductor layer (not illustrated).

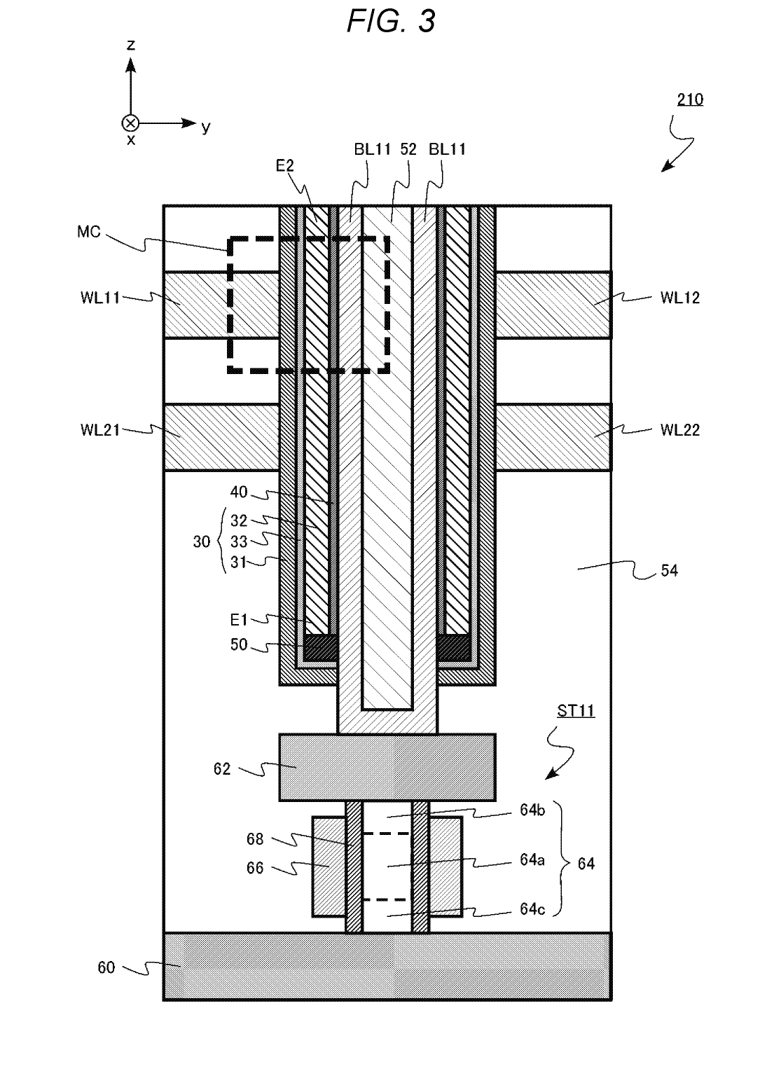

FIG. 3 is a schematic cross-sectional view of the memory cell array 210 of the memory device according to the first embodiment. FIG. 3 is a cross-section view of a region surrounded by a dotted line in FIG. 2 taken along a y-z direction. In FIG. 3, the region surrounded by the dotted line corresponds to one memory cell MC.

FIG. 3 illustrates the word line WL11 (first conductive layer), the word line WL12, word line WL21, the word line WL22, and the bit line BL11 (second conductive layer). In FIG. 3, the select transistor ST11 is also illustrated.

The memory cell array 210 includes a variable resistance layer 30, an intermediate layer 40, an insulator 50, a polycrystalline silicon layer 52, an interlayer insulating layer 54, a drain electrode 60 (fourth conductive layer), a source electrode 62 (third conductive layer), a semiconductor layer 64, a gate electrode 66, and a gate insulating layer 68. The semiconductor layer 64 includes a channel region 64a, a source region 64b, and a drain region 64c. The select transistor ST11 is formed with the drain electrode 60, the source electrode 62, the semiconductor layer 64, the gate electrode 66, and the gate insulating layer 68.

The word line WL11 extends in the x-direction (first direction). The word line WL11 is made of, for example, a metal. The word line WL is made of, for example, titanium nitride (TiN) or tungsten (W).

The bit line BL11 extends in the z-direction (second direction). The bit line BL11 is made of, for example, a metal. The bit line BL11 is made of, for example, titanium nitride (TiN) or tungsten (W).

The bit line BL11 is electrically connected to the source electrode 62. The bit line BL11 is in contact with the source electrode 62.

The word line WL11, the word line WL12, the word line WL21, and the word line WL22 are electrically separated from each other by the interlayer insulating layer 54. The interlayer insulating layer 54 is formed of, for example, silicon oxide.

The variable resistance layer 30 is provided between the word line WL11 and the bit line BL11. The variable resistance layer 30 includes a high resistance layer 31 (first layer), a low resistance layer 32 (second layer), and a reaction inhibition layer 33.

In the variable resistance layer 30, the high resistance layer 31, the reaction inhibition layer 33, and the low resistance layer 32 are arranged in this order from the word line WL11 toward the bit line BL11. A thickness of the variable resistance layer 30 is, for example, 5 nm or more and 25 nm or less in a y-direction (third direction). The y-direction (third direction) is orthogonal to the x-direction (first direction) and the z-direction (second direction).

The high resistance layer 31 contains a semiconductor or a first metal oxide. The high resistance layer 31 contains, for example, an amorphous semiconductor or an amorphous metal oxide.

The high resistance layer 31 is formed of, for example, the semiconductor. The high resistance layer 31 contains, for example, silicon, germanium, tin, or, silicon germanide. The high resistance layer 31 contains, for example, amorphous silicon, amorphous germanium, or amorphous silicon germanide.

The high resistance layer 31 is formed of, for example, the first metal oxide. The first metal oxide contains, for example, at least one metal element selected from the group consisting of aluminum (Al), hafnium (Hf), zirconium (Zr), tantalum (Ta), and niobium (Nb). The high resistance layer 31 is formed of, for example, aluminum oxide, hafnium oxide, zirconium oxide, tantalum oxide, niobium oxide, or a compound thereof.

The high resistance layer 31 has a thickness, for example, of 1 nm or more and 10 nm or less.

The low resistance layer 32 is provided between the high resistance layer 31 and the bit line BL11.

The low resistance layer 32 contains a second metal oxide. The second metal oxide contains, for example, at least one metal element selected from the group consisting of titanium (Ti), niobium (Nb), tantalum (Ta), and tungsten (W). The low resistance layer 32 is formed of, for example, titanium oxide, niobium oxide, tantalum oxide, or tungsten oxide. For example, the second metal oxide is different from the first metal oxide.

The low resistance layer 32 has resistivity lower than that of the high resistance layer 31. At least a part of the low resistance layer 32 has a crystalline structure. The low resistance layer 32 has, for example, a polycrystalline structure. The resistivity is lowered by crystallization of the second metal oxide of the low resistance layer 32. The metal oxide of the low resistance layer 32 has a crystallization ratio higher than that of the first metal oxide of the high resistance layer 31. The crystallization ratio of the metal oxide can be measured using, for example, TEM.

The low resistance layer 32 has a thickness of, for example, 3 nm or more and 15 nm or less.

The low resistance layer 32 includes a first end E1 and a second end E2. The second end E2 is spaced from the source electrode 62 farther than the first end E1. In other words, the first end E1 is closer to the select transistor ST11 farther than the second end E2.

The reaction inhibition layer 33 is provided between the high resistance layer 31 and the low resistance layer 32. The reaction inhibition layer 33 is formed of an amorphous material. The reaction inhibition layer 33 is formed of, for example, an oxide, a nitride, or an oxynitride.

The reaction inhibition layer 33 is formed of, for example, an oxide, a nitride, or an oxynitride containing at least one element selected from the group consisting of aluminum (Al), silicon (Si), and germanium (Ge). The reaction inhibition layer 33 is formed of, for example, aluminum oxide, silicon oxide, germanium oxide, aluminum nitride, silicon nitride, germanium nitride, aluminum oxynitride, silicon oxynitride, or germanium oxynitride.

The reaction inhibition layer 33 has, for example, a different composition from the high resistance layer 31 and the low resistance layer 32. The reaction inhibition layer 33 has a function of inhibiting the reaction of the high resistance layer 31 with the low resistance layer 32.

The reaction inhibition layer 33 has a thickness of, for example, 0.2 nm or more and 1 nm or less in the y-direction.

The intermediate layer 40 is provided between the variable resistance layer 30 and the bit line BL11. The intermediate layer 40 is provided between the low resistance layer 32 and the bit line BL11. The intermediate layer 40 has resistivity higher than that of the low resistance layer 32. The intermediate layer 40 is in an amorphous state. The intermediate layer 40 is formed of, for example, an oxide, a nitride, or an oxynitride.

The intermediate layer 40 contains, for example, a third metal oxide. The third metal oxide contains at least one metal element selected from the group consisting of, for example, aluminum (Al), hafnium (Hf), zirconium (Zr), tantalum (Ta), lanthanum (La), and niobium (Nb). The intermediate layer 40 is formed of, for example, aluminum oxide, hafnium oxide, zirconium oxide, lanthanum oxide, tantalum oxide, or niobium oxide.

The intermediate layer 40 is formed of, for example, an oxide, a nitride, or an oxynitride containing at least one element selected from the group consisting of silicon (Si) and germanium (Ge). The intermediate layer 40 is formed of, for example, silicon oxide, germanium oxide, silicon nitride, germanium nitride, silicon oxynitride, or germanium oxynitride.

The intermediate layer 40 is formed of, for example, a metal oxide or a metal oxynitride containing silicon (Si) and a metal element. The intermediate layer 40 is formed of, for example, aluminum silicate, hafnium silicate, nitrogen-added aluminum silicate, or nitrogen-added hafnium silicate.

The intermediate layer 40 is formed of, for example, a metal nitride or a metal oxynitride. The intermediate layer 40 is formed of, for example, aluminum nitride, hafnium nitride, aluminum oxynitride, or hafnium oxynitride.

The intermediate layer 40 has a different composition from, for example, the high resistance layer 31 and the low resistance layer 32. The intermediate layer 40 has a function of inhibiting diffusion of atoms between the low resistance layer 32 and the bit line 11.

The intermediate layer 40 has a thickness of, for example, 0.2 nm or more and 3 nm or less in the y-direction.

When a voltage is applied to the variable resistance layer 30 to pass a current, the variable resistance layer 30 changes into a low resistance state from a high resistance state, or changes into a high resistance state from a low resistance state. The change into the low resistance state from the high resistance state is referred to as a set operation, for example. The change into the high resistance state from the low resistance state is referred to as a reset operation, for example. A voltage applied to the variable resistance layer 30 during the change into the low resistance state from the high resistance state is referred to as a set voltage, and a voltage applied to the variable resistance layer 30 during the change into the high resistance state from the low resistance state is referred to as a reset voltage.

The oxygen deficiency amount (the quantity of oxygen vacancies) or the oxygen deficiency distribution in the low resistance layer 32 changes due to the voltage applied to the variable resistance layer 30. As the oxygen deficiency amount or the oxygen deficiency distribution in the low resistance layer 32 changes, the conductivity of the variable resistance layer 30 changes.

For example, the high resistance state is defined as data “0”, and the low resistance state is defined as data “1”. The memory cell MC can store 1-bit data of “0” or “1”.

The insulator 50 is provided between the first end E1 of the low resistance layer 32 and the bit line BL11. The insulator 50 has resistivity higher than that of the low resistance layer 32. The insulator 50 is in contact with the low resistance layer 32, the bit line BL11, and the intermediate layer 40.

The insulator 50 is formed of, for example, an oxide, a nitride, or an oxynitride.

The insulator 50 is formed of an oxide, a nitride, or an oxynitride containing at least one element selected from the group consisting of, for example, silicon (Si) and germanium (Ge). The insulator 50 is formed of, for example, silicon oxide, germanium oxide, silicon nitride, germanium nitride, silicon oxynitride, or germanium oxynitride.

The insulator 50 contains, for example, a fourth metal oxide. The fourth metal oxide contains at least one metal element selected from the group consisting of, for example, aluminum (Al), hafnium (Hf), zirconium (Zr), tantalum (Ta), lanthanum (La), and niobium (Nb). The insulator 50 is formed of, for example, aluminum oxide, hafnium oxide, zirconium oxide, lanthanum oxide, tantalum oxide, or niobium oxide.

The insulator 50 is formed of, for example, a metal oxide or a metal oxynitride containing silicon (Si) and a metal element. The insulator 50 is formed of, for example, aluminum silicate, hafnium silicate, nitrogen-added aluminum silicate, or nitrogen-added hafnium silicate.

The insulator 50 is formed of, for example, a metal nitride or a metal oxynitride. The insulator 50 is formed of, for example, aluminum nitride, hafnium nitride, aluminum oxynitride, or hafnium oxynitride.

The insulator 50 has a different composition from, for example, the low resistance layer 32 and the intermediate layer 40. The insulator 50 has a function of inhibiting a leakage current flowing between the first end E1 of the low resistance layer 32 and the bit line BL11.

For example, when the low resistance layer 32 is formed of titanium oxide, the insulator 50 is formed of silicon oxide, silicon nitride, silicon oxynitride, aluminum oxide, or aluminum nitride that has resistivity higher than that of the titanium oxide. Further, when the intermediate layer 40 is formed of aluminum oxide, the insulator 50 is formed of, for example, silicon oxide having resistivity higher than that of the aluminum oxide.

The polycrystalline silicon layer 52 is provided between the bit lines BL11. Instead of the polycrystalline silicon layer 52, a tungsten layer can also be used.

The semiconductor layer 64 is provided between the drain electrode 60 and the source electrode 62. The semiconductor layer 64 includes the channel region 64a, the source region 64b, and the drain region 64c. The semiconductor layer 64 is formed of, for example, polycrystalline silicon.

The channel region 64a is formed of, for example, a p-type semiconductor containing a p-type impurity as a conductive impurity. The p-type impurity is, for example, boron (B). The channel region 64a may be an intrinsic semiconductor. The source region 64b and the drain region 64c are formed of, for example, an n-type semiconductor containing an n-type impurity as a conductive impurity. The n-type impurity is, for example, phosphorus (P) or arsenic (As).

The drain electrode 60 is the global bit line GBL of the resistance-change type memory 100.

The drain electrode 60 is formed of, for example, a metal or a metal semiconductor compound. The drain electrode 60 has a stacked structure of titanium nitride (TiN) and tungsten (W), for example. For example, the titanium nitride (TiN) is provided between the tungsten (W) and the semiconductor layer 64.

The source electrode 62 is electrically connected to the bit line BL11. The source electrode 62 is formed of, for example, a metal or a metal semiconductor compound. The source electrode 62 has a stacked structure of titanium nitride (TiN) and tungsten (W), for example. For example, the titanium nitride (TiN) is provided between the tungsten (W) and the semiconductor layer 64.

The gate electrode 66 is formed of, for example, a metal, a metal semiconductor compound, or a semiconductor. The gate electrode 66 is formed of, for example, titanium nitride (TiN).

The gate insulating layer 68 is provided between the gate electrode 66 and a side surface of the semiconductor layer 64. The gate insulating layer 68 is provided in contact with the semiconductor layer 64.

The gate insulating layer 68 is formed of an oxide or an oxynitride. The gate insulating layer 68 contains at least one substance selected from the group consisting of, for example, silicon oxide, silicon oxynitride, hafnium oxide, hafnium silicate, and nitrogen-added hafnium silicate.

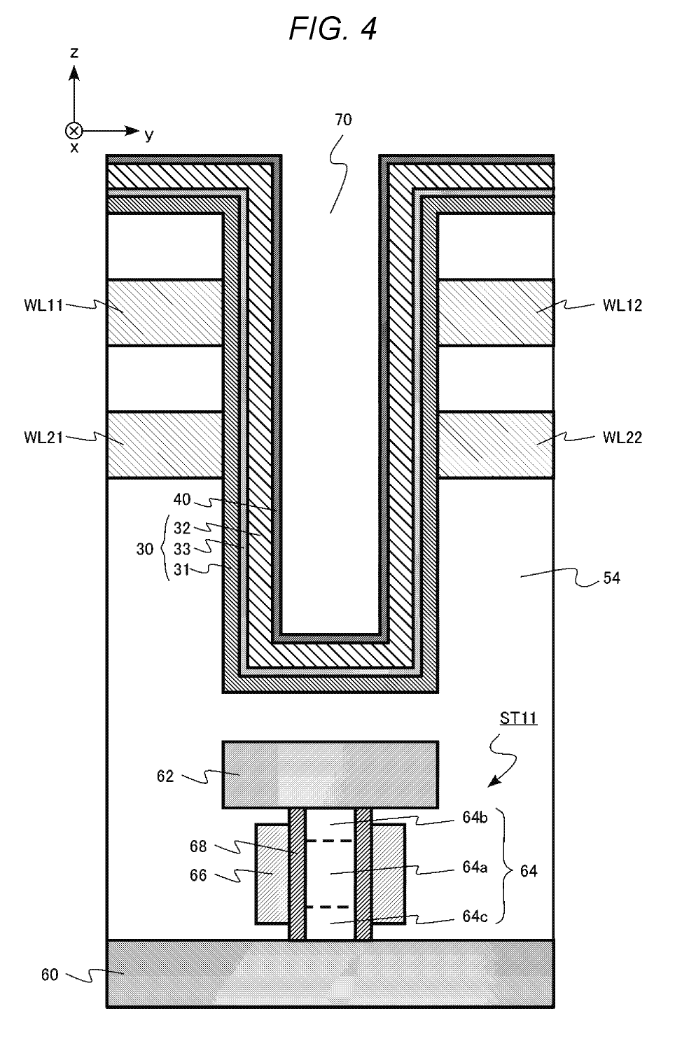

An example of a manufacturing method of the memory device according to the first embodiment will be described below. FIGS. 4 to 10 are schematic cross-sectional views illustrating the memory device which is being manufactured by a method of manufacturing the memory device according to the first embodiment.

First, the drain electrode 60, the source electrode 62, the semiconductor layer 64, the gate electrode 66, and the gate insulating layer 68 is formed by the known process technique to form the select transistor ST11. Next, the word line WL11, the word line WL12, the word line WL21, the word line WL22, and the interlayer insulating layer 54 are formed by the known process technique.

Subsequently, the high resistance layer 31, the reaction inhibition layer 33, the low resistance layer 32, and the intermediate layer 40 are formed in a groove 70 provided in the word line WL11, the word line WL12, the word line WL21, the word line WL22, and the interlayer insulating layer 54 using, for example, atomic layer deposition (ALD) or chemical vapor deposition (CVD) (see FIG. 4).

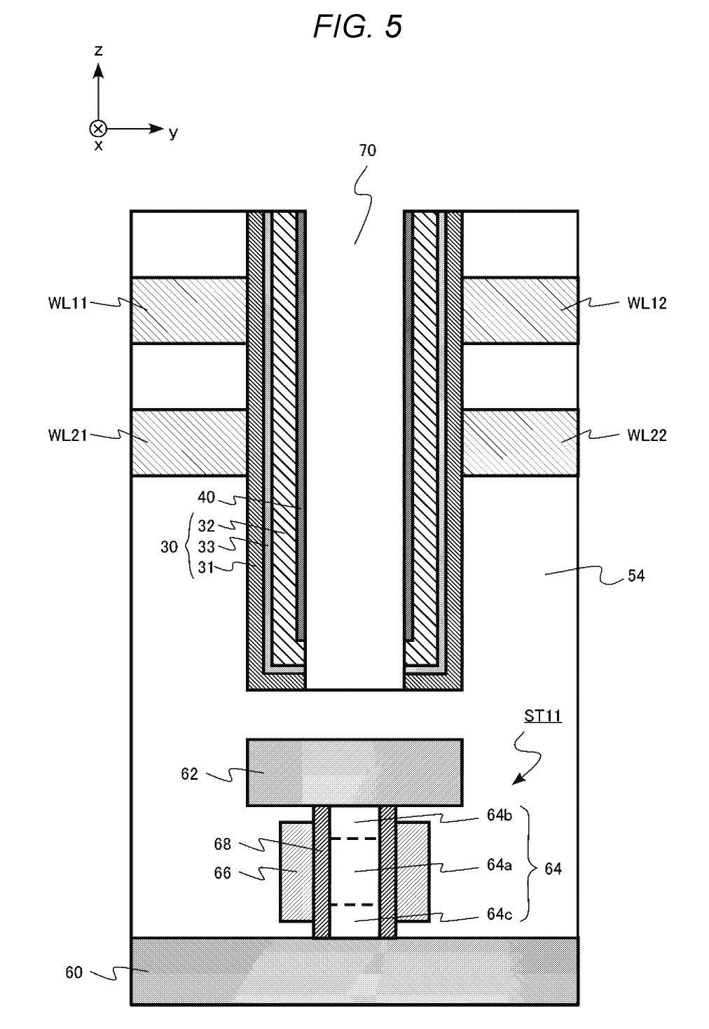

Next, the intermediate layer 40, the low resistance layer 32, the reaction inhibition layer 33, and the high resistance layer 31 on the bottom of the groove 70 are removed using, for example, anisotropic dry etching (see FIG. 5).

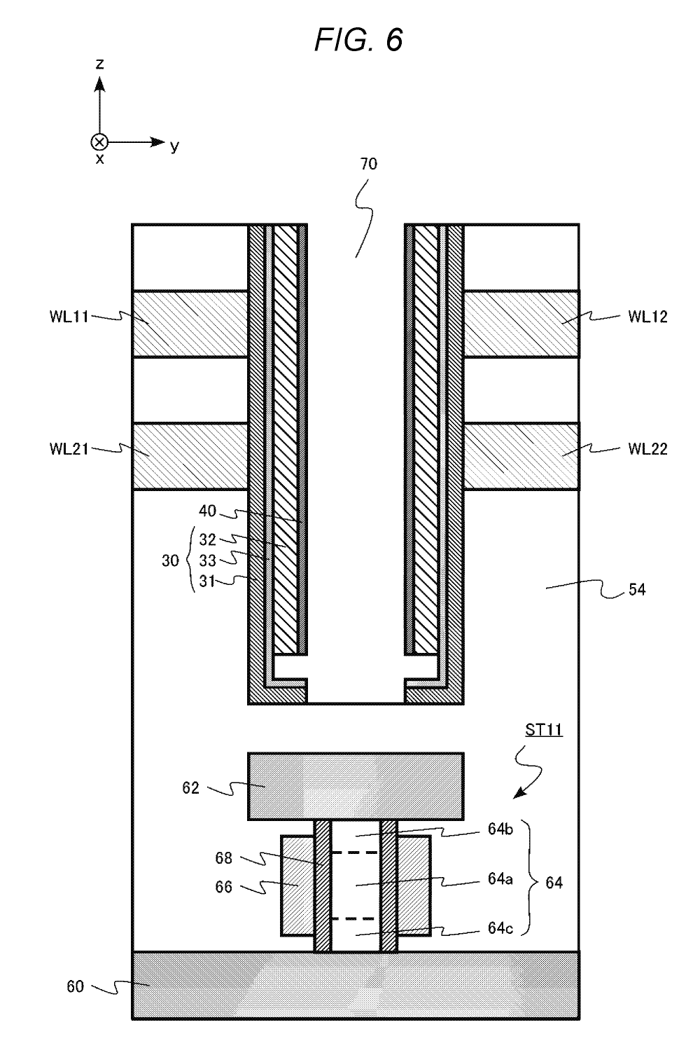

A part of the low resistance layer 32 on the bottom of the groove 70 is removed using, for example, isotropic dry etching or wet etching (see FIG. 6). The low resistance layer 32 is selectively removed with respect to the intermediate layer 40.

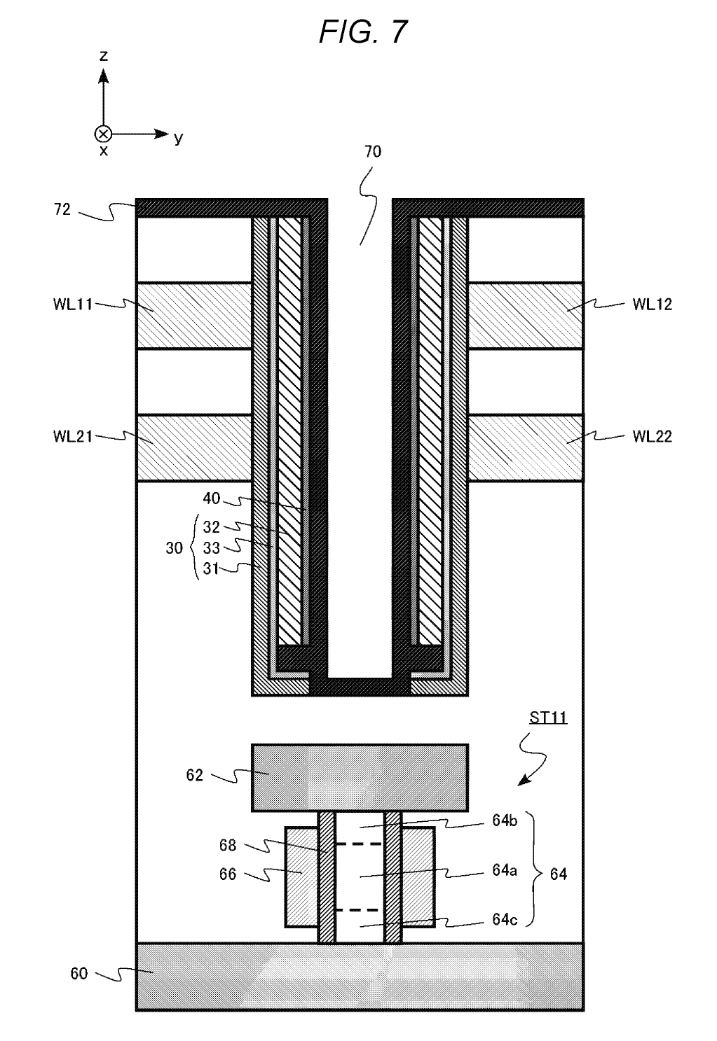

Next, an insulating film 72 is formed in the groove 70 using, for example, ALD or CVD (see FIG. 7).

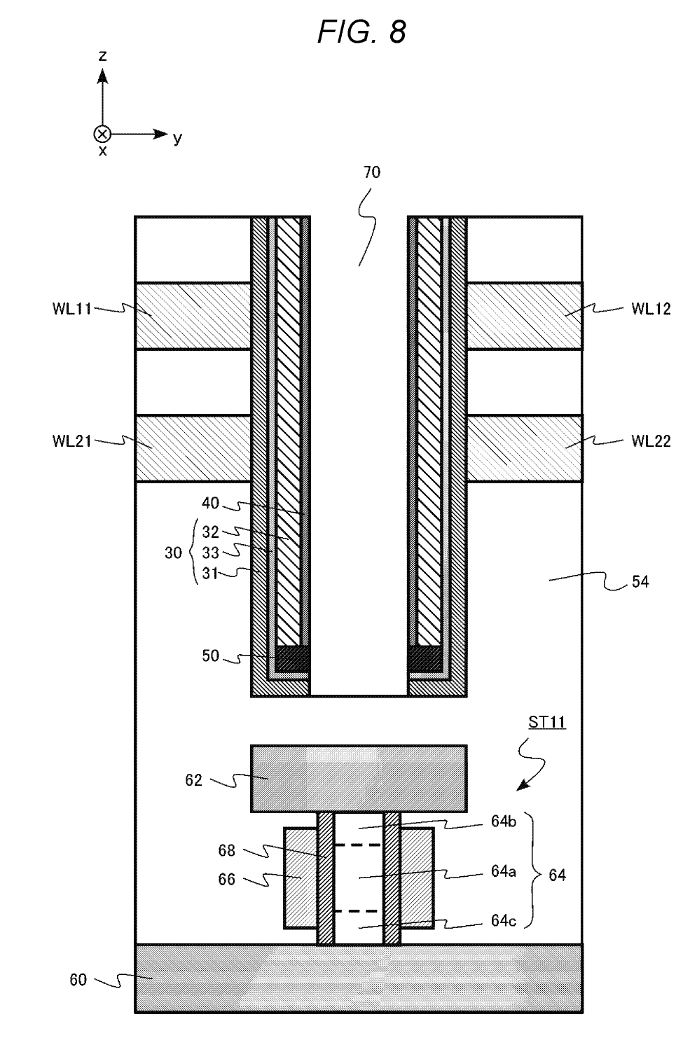

Subsequently, apart of the insulating film 72 is removed using, for example, isotropic dry etching or wet etching to form the insulator 50 (see FIG. 8).

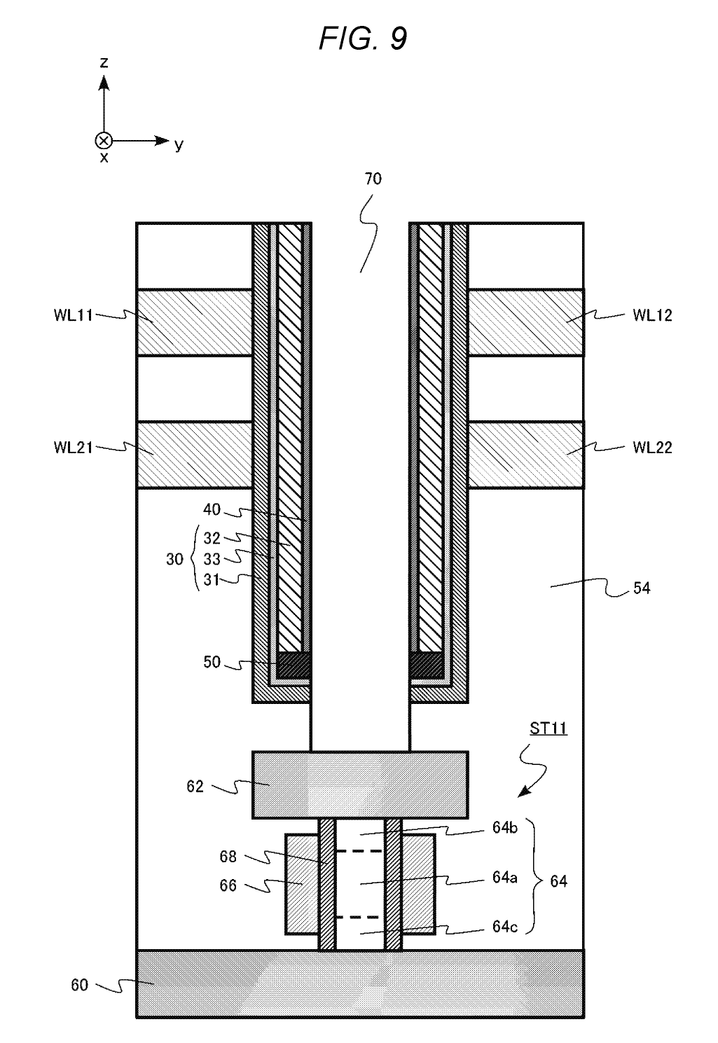

Next, the interlayer insulating layer 54 on the bottom of the groove 70 is removed using, for example, anisotropic dry etching to expose the source electrode 62 (see FIG. 9).

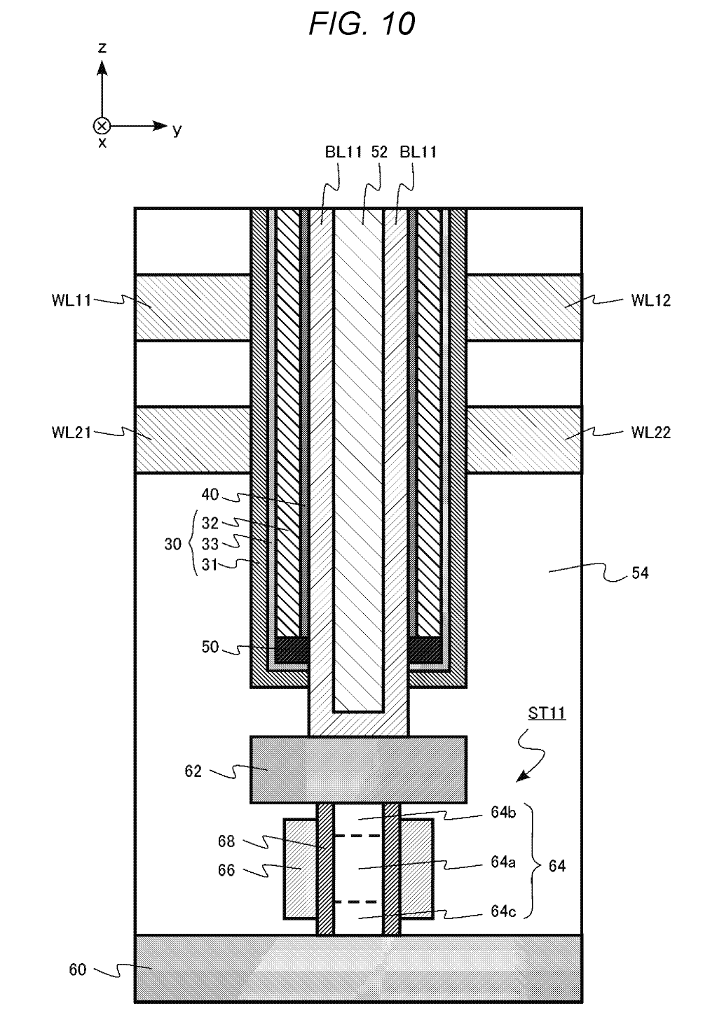

Next, a material film of the bit line BL11 and a polycrystalline silicon film are deposited in the groove 70 using, for example, ALD or CVD. Thereafter, the material film of the bit line BL11 and the polycrystalline silicon film are polished by, for example, chemical mechanical polishing (CMP) to form the bit line BL11 and the polycrystalline silicon layer 52 (see FIG. 10).

The resistance-change type memory 100 of the first embodiment illustrated in FIG. 3 is manufactured by the manufacturing method described above.

The operation and effect of the memory device according to the first embodiment will be described.

In the resistance-change type memory which changes the conductivity of the variable resistance layer 30 using a change in the oxygen deficiency amount or a change in the oxygen deficiency distribution, the characteristics of the memory cell MC may be degraded due to repetition of the set operation and the reset operation. Specifically, for example, a resistance ratio between the high resistance state and the low resistance state becomes small. When the resistance ratio between the high resistance state and the low resistance state becomes small, read margin of data from the memory cell MC decreases, which is a problem.

For example, there is a method of increasing the set voltage or the reset voltage depending on the number of repetitions of the set operation and the reset operation in order to compensate the read margin of data. However, when the set voltage or the reset voltage becomes too high, dielectric breakdown of the variable resistance layer 30 occurs and the memory cell MC does not operate.

Therefore, it is required to prevent the degradation in characteristic of the memory cell MC and to improve the reliability of the resistance-change type memory.

In the resistance-change type memory 100 of the first embodiment, the intermediate layer 40 is provided between the low resistance layer 32 of the variable resistance layer 30 and the bit line BL11. The formation of the intermediate layer 40 prevents degradation in characteristic of the memory cell MC.

The reason why the formation of the intermediate layer 40 prevents the degradation in characteristic of the memory cell MC is considered as follows. When the intermediate layer 40 is not provided, constituent atoms of the bit line BL11 diffuse into the low resistance layer 32 or the high resistance layer 31 through a grain boundary of the low resistance layer 32 when the set operation and the reset operation are repeated. For example, when the bit line BL11 is formed of titanium nitride, constituent atoms of the titanium nitride, that is, titanium and nitrogen diffuse into the low resistance layer 32 or the high resistance layer 31. The diffusion of the constituent atoms of the bit line BL11 into the low resistance layer 32 or the high resistance layer 31 is considered as one of factors causing the degradation in characteristic of the memory cell MC.

The intermediate layer 40 is in an amorphous state in which no grain boundary exists. When the intermediate layer 40 is provided, it is possible to prevent the diffusion of the constituent atoms of the bit line BL11 into the low resistance layer 32 or the high resistance layer 31. Therefore, the formation of the intermediate layer 40 prevents the degradation in characteristic of the memory cell MC. Thus, the reliability of the resistance-change type memory is improved.

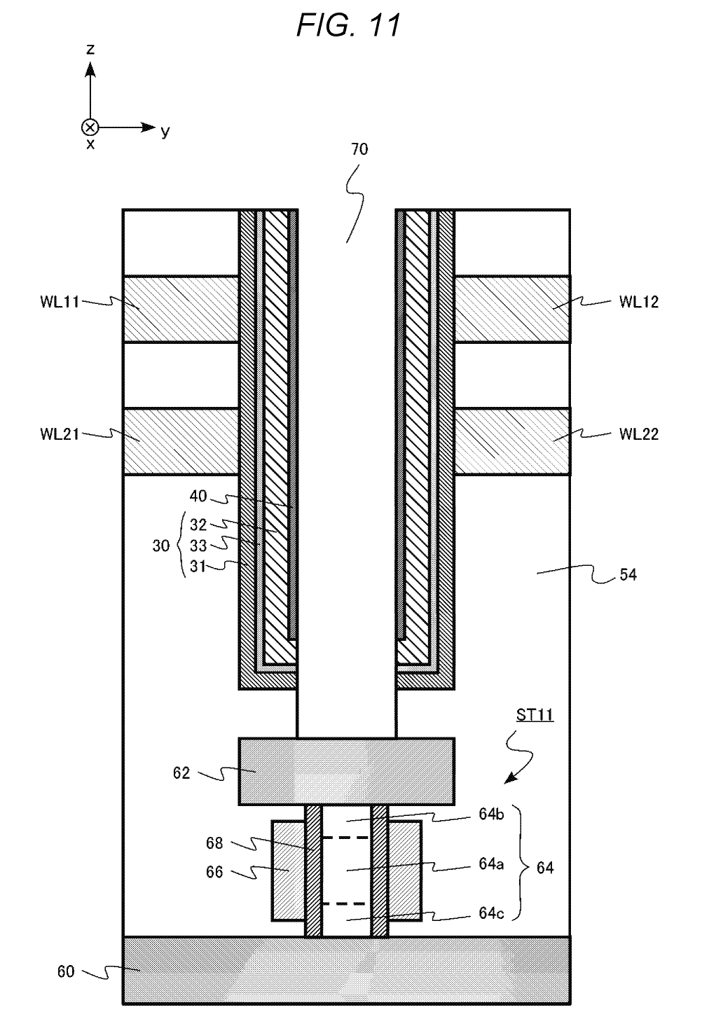

FIG. 11 is a schematic cross-sectional view of a memory device which is being manufactured in a method of manufacturing the memory device according to a comparative example. The method of manufacturing the memory device according to the comparative example differs from the manufacturing method according to the first embodiment in that there is no process of forming the insulator 50.

After forming a structure similar to that in FIG. 5 according to the first embodiment, the interlayer insulating layer 54 on the bottom of the groove 70 is removed by, for example, anisotropic dry etching to expose the source electrode 62 (FIG. 11).

Next, a material film of the bit line BL11 and a polycrystalline silicon film are deposited in the groove 70 using, for example, ALD or CVD. Thereafter, the material film of the bit line BL11 and the polycrystalline silicon film are polished by, for example, chemical mechanical polishing (CMP) to form the bit line BL11 and the polycrystalline silicon layer 52.

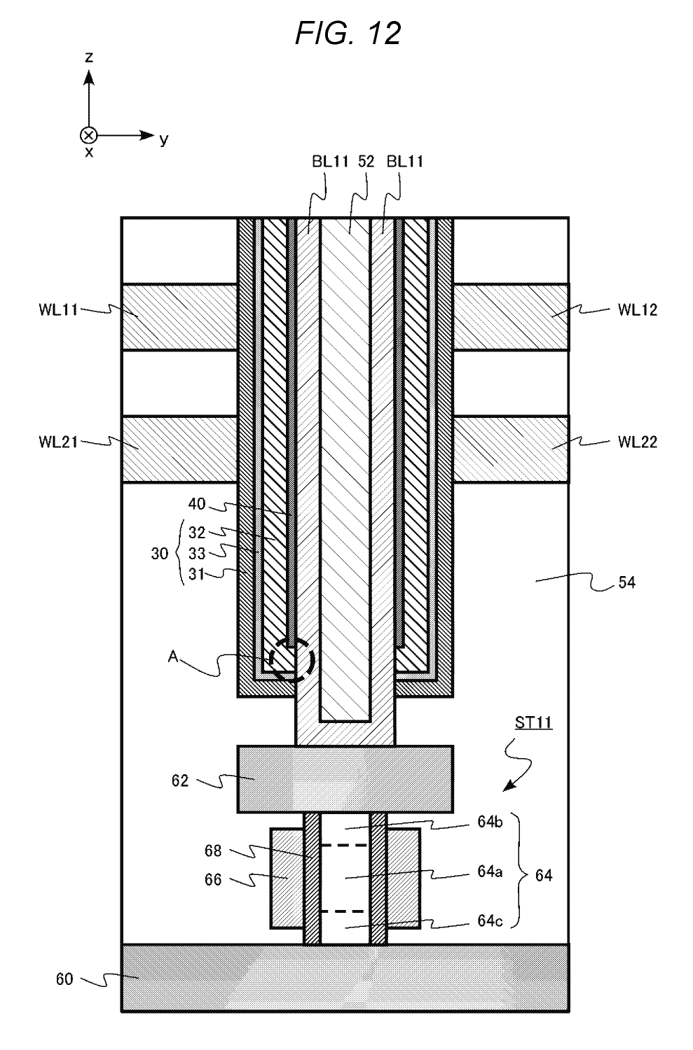

FIG. 12 is a schematic cross-sectional view of a memory cell array of the memory device according to the comparative example. A resistance-change type memory of the comparative example illustrated in FIG. 12 is manufactured by the manufacturing method described above. In the case of the resistance-change type memory according to the comparative example, since the insulator 50 does not exist, there is a contact portion (indicated by A in FIG. 12) where the low resistance layer 32 and the bit line BL11 are in direct contact with each other.

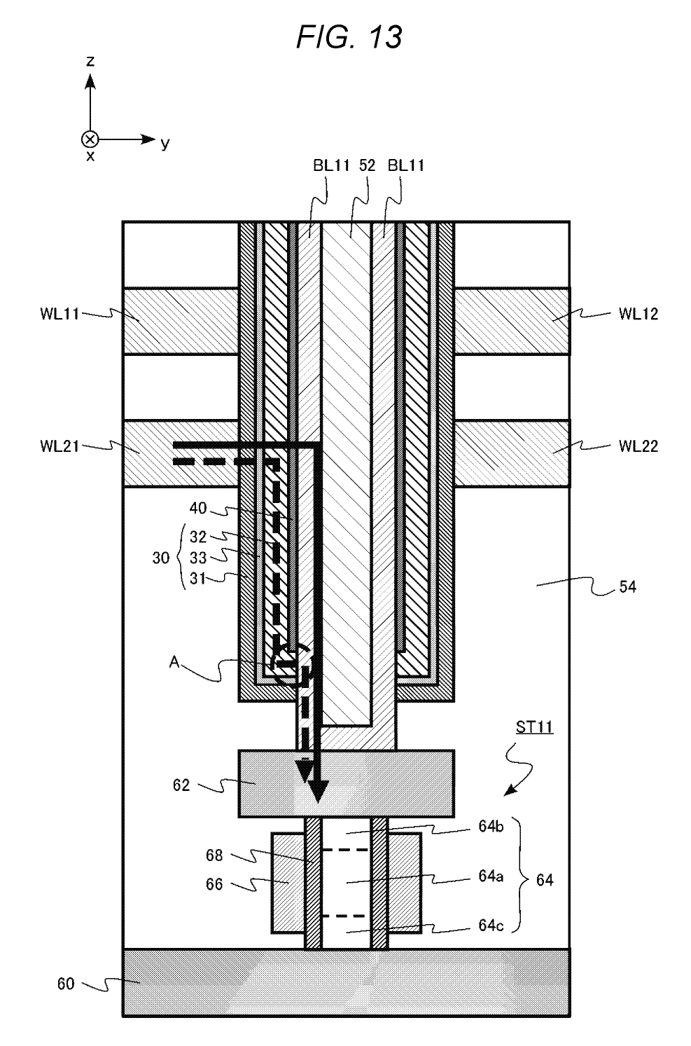

FIG. 13 is a view for describing problems of the memory device according to the comparative example.

For example, there is considered a case where a voltage is applied between the word line WL21 and the bit line BL11, that is, a case where a voltage is applied between the word line WL21 and the source electrode 62. In this case, a current flows originally in a current path indicated by the solid arrow.

However, when there is a contact portion (indicated by A in FIG. 13) where the low resistance layer 32 and the bit line BL11 are in direct contact with each other, a current flows in a leakage current path indicated by a dotted arrow. For this reason, malfunction such as erroneous writing or erroneous reading of the memory cell MC may occur. The leakage current path occurs because the resistivity of the low resistance layer 32 is lower than the resistivity of the intermediate layer 40.

In the resistance-change type memory 100 according to the first embodiment, the insulator 50 is provided between the first end E1 of the low resistance layer 32 and the bit line BL11. Thus, the low resistance layer 32 does not directly contact with the bit line BL11. The insulator 50 has the resistivity higher than that of the low resistance layer 32. Therefore, the occurrence of the leakage current path is prevented. Accordingly, the malfunction of the memory cell MC is prevented.

From the viewpoint of preventing the occurrence of the leakage current path, the resistivity of the insulator 50 is preferably higher than the resistivity of the intermediate layer 40. Further, from the viewpoint of prevention the occurrence of the leakage current path, the thickness of the insulator 50 in the y-direction (third direction) is preferably thicker than the thickness of the intermediate layer 40 in the y-direction.

From the viewpoint of preventing the occurrence of the leakage current path and the ease of manufacturing, the insulator 50 is preferably formed of silicon oxide, silicon nitride, or silicon oxynitride.

As described above, according to the memory device of the first embodiment, the leakage current path is prevented from occurring between the word line WL and the bit line BL. Accordingly, it is possible to achieve a memory device capable of preventing the malfunction of the memory cell MC.

### Second Embodiment

A memory device of a second embodiment is similar to that of the first embodiment except that the insulator 50 includes voids (cavities). The description will not be made below with respect to the same contents as those of the first embodiment.

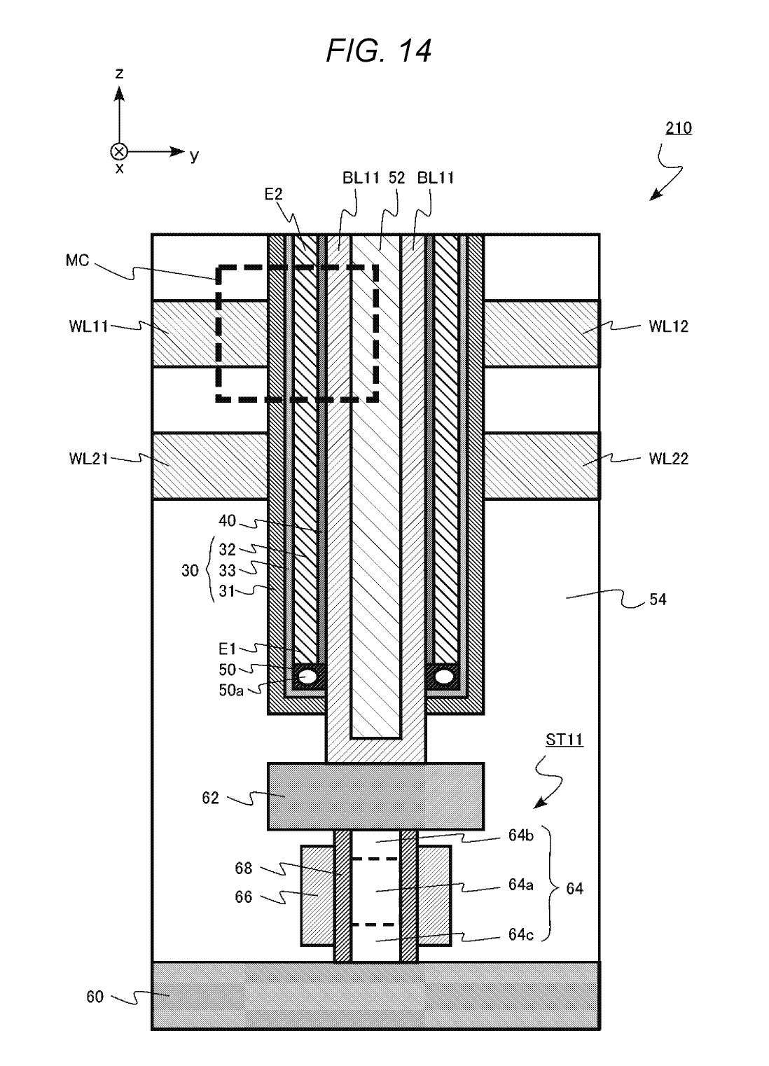

FIG. 14 is a schematic cross-sectional view of a memory cell array 210 of a memory device according to the second embodiment.

In the resistance-change type memory according to the second embodiment, the insulator 50 includes a void 50a. The void 50a has resistivity higher than that of the low resistance layer 32.

The insulator 50 may be completely provided in the form of the void.

According to the memory device of the second embodiment, it is possible to achieve a memory device capable of preventing the malfunction of the memory cell MC as in the memory device of the first embodiment.

### Third Embodiment

A memory device according to a third embodiment is similar to that of the first embodiment except that the high resistance layer is divided between the word lines WLs. The description will not be made below with respect to the same contents as those of the first embodiment.

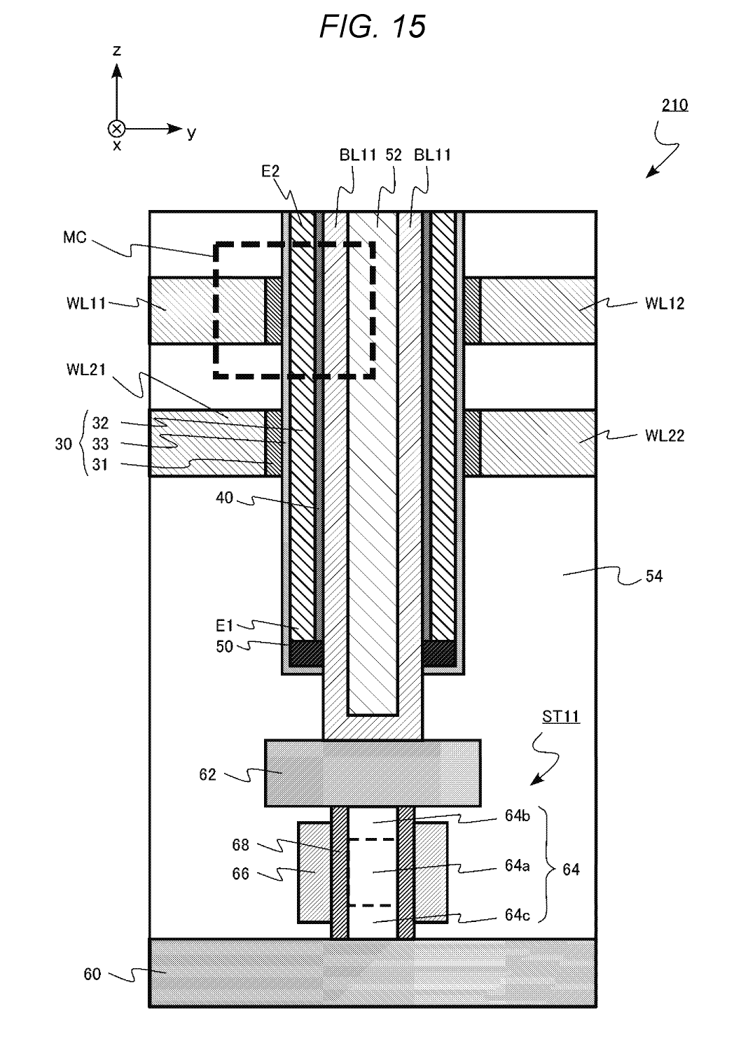

FIG. 15 is a schematic cross-sectional view of a memory cell array 210 of the memory device according to the third.

In the resistance-change type memory according to the third embodiment, the high resistance layer 31 is divided between the word lines WLs. For example, the high resistance layer 31 does not exist between the word line WL11 and the word line WL21.

The reaction inhibition layer 33 may be divided between the word lines WLs.

According to the memory device of the third embodiment, it is possible to achieve a memory device capable of preventing the malfunction of the memory cell MC as in the memory device of the first embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
a first conductive layer extending in a first direction;
a second conductive layer extending in a second direction intersecting with the first direction;
a third conductive layer electrically connected to the second conductive layer;
a variable resistance layer including a first layer containing a semiconductor or a first metal oxide, and a second layer, the second layer located between the first layer and the second conductive layer and also located between the first conductive layer and the second conductive layer, the second layer containing a second metal oxide, the second layer including a first end and a second end, the second end spaced farther from the third conductive layer than the first end;
an intermediate layer disposed between the variable resistance layer and the second conductive layer, the intermediate layer having a resistivity higher than that of the second layer; and
an insulator disposed between the first end and the second conductive layer, the insulator having a resistivity higher than that of the second layer.

2. The memory device according to claim 1, wherein
the insulator has a resistivity higher than that of the intermediate layer.

3. The memory device according to claim 1, wherein
the insulator is in contact with the second layer and the second conductive layer.

4. The memory device according to claim 1, wherein
the insulator has a thickness larger than that of the intermediate layer in a third direction orthogonal to the first direction and the second direction.

5. The memory device according to claim 1, further comprising:
a fourth conductive layer;
a semiconductor layer disposed between the fourth conductive layer and the third conductive layer;
a gate electrode; and
a gate insulating layer disposed between the gate electrode and the semiconductor layer.

6. The memory device according to claim 1, wherein the first conductive layer includes a first conductive layer region and a second conductive layer region separated from the first conductive layer region, the first layer includes a first layer region and a second layer region separated from the first layer region, the first conductive layer region contacting the first layer region, and the second conductive layer region contacting the second layer region.

7. The memory device according to claim 6, further comprising a reaction inhibition layer,
wherein the reaction inhibition layer includes a first reaction inhibition layer and a second reaction inhibition layer separated from the first reaction inhibition layer, the first reaction inhibition layer contacting the first layer region, and the second reaction inhibition layer contacting the second layer region.

8. The memory device according to claim 1, wherein the insulator includes at least one void.

9. The memory device according to claim 8, wherein the insulator is entirely comprised of a void.

10. The memory device according to claim 1, wherein the first layer has a higher resistance than that of the second layer.

11. The memory device according to claim 10, wherein the first layer contains an amorphous semiconductor or an amorphous metal oxide.

12. The memory device according to claim 1, wherein the second layer crystallization ratio is higher than that of the first layer.

13. The memory device according to claim 1, further comprising a reaction inhibition layer disposed between the first layer and the second layer which inhibits the reaction of the first layer with the second layer.

14. The memory device according to claim 13, wherein the reaction inhibition layer includes an amorphous material.

15. The memory device according to claim 1, wherein the intermediate layer includes a diffusion inhibition material which inhibits diffusion of atoms between the second layer and the second conductive layer.

16. The memory device according to claim 1, wherein the insulator contacts the second layer, the second conductive layer and the intermediate layer.

17. A method of making a memory device comprising:
forming a first conductive layer extending in a first direction;
forming a second conductive layer extending in a second direction intersecting with the first direction;
forming a third conductive layer electrically connected to the second conductive layer;
forming a variable resistance layer including a first layer containing a semiconductor or a first metal oxide, and a second layer, the second layer located between the first layer and the second conductive layer and also located between the first conductive layer and the second conductive layer, the second layer containing a second metal oxide, the second layer including a first end and a second end, the second end spaced farther from the third conductive layer than the first end;
forming an intermediate layer between the variable resistance layer and the second conductive layer, the intermediate layer having a resistivity higher than that of the second layer; and
forming an insulator between the first end and the second conductive layer, the insulator having a resistivity higher than that of the second layer.
